(19) United States
(12) Patent Application Publication
(10) Pub. No.: US 2017/0111036 A1
(43) Pub. Date: Apr. 20, 2017

(54) DUTY CYCLE DETECTOR CIRCUIT

(71) Applicant: SK hynix Inc., Gyeonggi-do (KR)

(72) Inventors: Young-Suk SEO, Gyeonggi-do (KR); Da-In IM, Gyeonggi-do (KR)

(21) Appl. No.: 15/145,519

(22) Filed: May 3, 2016

(30) Foreign Application Priority Data
Oct. 19, 2015 (KR) 10-2015-0145207

(51) Int. Cl. H03K 5/19

(52) U.S. Cl. CPC H03K 5/19

(57) ABSTRACT

A duty cycle detector (DCD) circuit may include: a duty cycle detector including one or more capacitor sets which are charged, discharged, or charged and discharged a clock, and suitable for detecting a duty cycle of the clock; and a frequency detector suitable for detecting a frequency of the clock. Each of the one or more capacitor sets has an adjustable capacity according to the frequency detection result of the frequency detector.

### CROSS-REFERENCE TO RELATED APPLICATIONS

The present application claims priority of Korean Patent Application No. 10-2015-0145207, filed on Oct. 19, 2015, which is incorporated herein by reference in its entirety.

### BACKGROUND

1. Field

This patent document relates to a duty cycle detector (DCD) circuit suitable for detecting a duty cycle of a clock in various integrated circuits.

2. Description of the Related Art

In integrated circuit chips, such as a CPU and a memory operating according to a clock, it is very important to precisely control the duty cycle (i.e. duty) of the clock. For example, when the duty cycle of the clock is not exactly 50%, the timing between the rising and falling edges may be distorted and cause malfunction of a memory storing and outputting data at rising and falling edges of the clock.

For correcting the duty cycle of the clock, it is required to precisely detect the duty cycle of the clock. Thus, there is a demand for a duty cycle detector circuit with high precision.

### SUMMARY

Various embodiments are directed to a duty cycle detector (DCD) circuit capable of detecting the duty cycle of a clock with high precision regardless of whether the frequency of the clock is high or low.

In an embodiment, a DCD circuit may include: a duty cycle detector including one or more capacitor sets which are charged, discharged, or charged and discharged by a clock, and suitable for detecting a duty cycle of the clock; and a frequency detector suitable for detecting a frequency of the clock. Each of the one or more capacitor sets may have an adjustable capacity according to the frequency detection result of the frequency detector.

Each of the one or more capacitor sets may decrease the capacity as the frequency of the clock becomes higher, and increase the capacity as the frequency of the clock becomes lower.

Each of the one or more capacitor sets may include: a plurality of capacitors coupled in parallel to one another; and a plurality of switches suitable for turning on/off the capacitors, respectively, according to the frequency detection result.

The frequency detector may include: a period setting unit suitable for enabling a counting period signal for a predetermined time; and a counter unit suitable for generating the frequency detection result by counting a number of enablement times of the clock during enablement of the counting period signal.

The period setting unit may include: a reference capacitor; a discharger suitable for charging the reference capacitor during disablement of a discharger enable signal, and discharging the reference capacitor during enablement of the discharger enable signal; a comparator suitable for comparing the voltage across the reference capacitor with the level of a reference voltage; and a period signal generator suitable for generating the counting period signal in response to the discharger enable signal and an output signal of the comparator.

The counter unit may include: a counting clock generator suitable for outputting the clock as a counting clock during enablement of the counting period signal, and deactivating the counting clock during disablement of the counting period signal; and a counter suitable for generating the frequency detection result by counting the number of enablement times of the counting clock.

The frequency detector may include: a pulse generator suitable for generating a pulse signal having a pulse width corresponding to N cycles of the clock, where N is an integer equal to or more than 1; a replica capacitor set as a replica of one of the capacitor sets; a discharger suitable for charging the replica capacitor set during disablement of the pulse signal, and discharging the replica capacitor set during enablement of the pulse signal; a comparator suitable for comparing the voltage across the replica capacitor set with the level of a reference voltage; and a successive approximation register (SAR) suitable for generating the frequency detection result in response to an output signal of the comparator.

The frequency detector may include: a pulse generator suitable for generating a pulse signal having a pulse width corresponding to N cycles of the clock, where N is an integer equal to or more than 1; a reference capacitor; a discharger suitable for charging the reference capacitor during disablement of the pulse signal, and discharging the reference capacitor during enablement of the pulse signal, wherein the discharger adjusts amount of discharge current according to the frequency detection result; a comparator suitable for comparing the voltage across the reference capacitor with the level of a reference voltage; and a SAR suitable for generating the frequency detection result in response to an output signal of the comparator.

The one or more capacitor sets may include first and second capacitor sets, and the duty cycle detector may discharge the first capacitor set when the clock is at a first level, discharge the second capacitor set when the clock is at a second level, and generate the duty cycle detection result by comparing the discharge amounts of the first and second capacitor sets.

The duty cycle detector may further include: a charger suitable for charging the first and second capacitor sets in response to a charge signal; a first discharger suitable for discharging the first capacitor set when the clock is at the first level; a second discharger suitable for discharging the second capacitor set when the clock is at the second level; and a comparator suitable for generating the duty cycle detection result by comparing the voltage across the first capacitor set to the voltage across the second capacitor set.

In an embodiment, a DCD circuit may include: a duty cycle detector including one or more capacitors which are charged, discharged, or charged and discharged by a clock, and suitable for detecting a duty cycle of the clock; and a frequency detector suitable for detecting a frequency of the clock. The duty cycle detector may adjust a charge current amount, a discharge current amount, or a charge and discharge current amount of the one or more capacitors according to the frequency detection result of the frequency detector.

The duty cycle detector may increase one or more of current for the charge and current for the discharge of each of the capacitors as the frequency of the clock becomes higher, and decrease one or more of current for the charge and current for the discharge of each of the capacitors as the frequency of the clock becomes lower.

The duty cycle detector may include a current source set suitable for adjusting one or more of current for the charge and current for the discharge of each of the capacitors, and the current source set may include: a plurality of current sources coupled in parallel to one another; and a plurality of switches suitable for turning on/off the current sources, respectively, according to the frequency detection result.

The one or more capacitor sets may include first and second capacitor sets, and the duty cycle detector may discharge the first capacitor set when the clock is at a first level, discharge the second capacitor set when the clock is at a second level, and generate the duty cycle detection result by comparing the discharge amounts of the first and second capacitors.

The duty cycle detector may further include: a charger suitable for charging the first and second capacitor sets in response to a charge signal; a first discharger suitable for discharging the first capacitor set when the clock is at the first level; a second discharger suitable for discharging the second capacitor set when the clock is at the second level; a current source set suitable for adjusting discharge current amounts of the first and second dischargers according to the frequency detection result; and a comparator suitable for generating the duty cycle detection result by comparing the voltage across the first capacitor set to the voltage across the second capacitor set.

In an embodiment, a DCD circuit may include: a duty cycle detector including one or more capacitor sets which are charged, discharged, or charged and discharged by a clock, and suitable for detecting a duty cycle of the clock; and a frequency detector suitable for detecting a frequency of the clock. Each of the one or more capacitor sets may have an adjustable capacity according to the frequency detection result of the frequency detector. The duty cycle detector may adjust a charge current amount, a discharge current amount, or a charge and discharge current amount of each of the capacitor set according to the frequency detection result of the frequency detector.

### BRIEF DESCRIPTION OF THE DRAWINGS

FIG. 1 is a configuration diagram of a duty cycle detector (DCD) circuit according to an embodiment of the present invention.

FIG. 2 is a timing diagram for describing an operation of the DCD circuit of FIG. 1.

FIG. 3 is a configuration diagram of a DCD circuit according to another embodiment of the present invention.

FIG. 4 is a configuration diagram of a DCD circuit according to another embodiment of the present invention.

FIG. 5 is a configuration diagram illustrating a first embodiment of a frequency detector of FIG. 3 or 4.

FIG. 6 is a configuration diagram illustrating a second embodiment of the frequency detector of FIG. 3 or 4.

FIG. 7 is a configuration diagram illustrating a third embodiment of the frequency detector of FIG. 3 or 4.

FIG. 8 is a configuration diagram of a DCD circuit according to another embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the present invention to those skilled in the art. Throughout the disclosure, like reference numerals refer to like parts throughout the various figures and embodiments of the present invention.

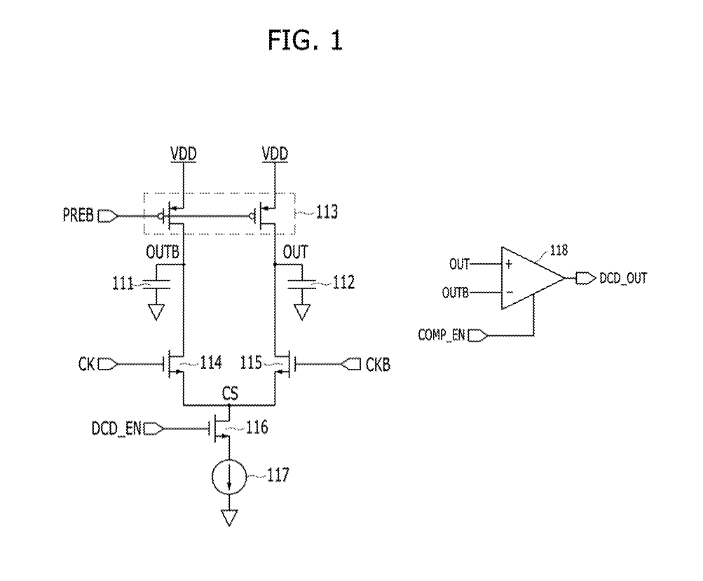

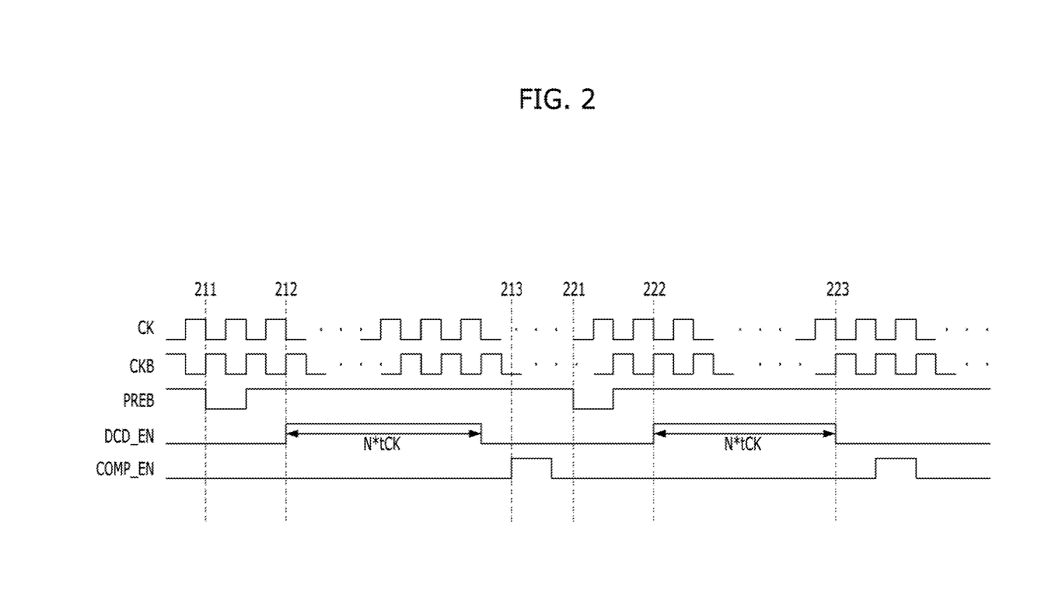

Referring now to FIG. 1 a configuration diagram of a duty cycle detector (DCD) circuit generally designated with numeral 100 is provided, according to an embodiment of the present invention. FIG. 2 is a timing diagram for describing an operation of the DCD circuit 100 of FIG. 1.

Referring to FIG. 1, the DCD circuit 100 may include a first capacitor 111, a second capacitor 112, a charger 113, a first discharger 114, a second discharger 115, an enable unit 116, a current source 117, and a comparator 118.

The charger 113 may charge the first and second capacitors 111 and 112 with a supply voltage VDD in response to a charge signal PREB. The charger 113 may include two PMOS transistors as illustrated in FIG. 1.

The first discharger 114 may discharge the first capacitor 111 when a clock CK is at a first level (for example, high level). The second discharger 115 may discharge the second capacitor 112 when the clock CK is at a second level (for example, low level) or when an inverted clock signal CKB, which is an inverted signal of the clock CK, is at a high level. As illustrated in FIG. 1, each of the first and second dischargers 114 and 115 may be or include an NMOS transistor.

The enable unit 116 may sink a current to a common source node CS through the current source 117 in response to enablement of an enable signal DCD_EN. As illustrated in FIG. 1, the enable unit 116 may include an NMOS transistor.

The comparator 118 may generate a duty cycle detection result DCD_OUT by comparing the voltage OUTB of the first capacitor 111 with the voltage OUT of the second capacitor 112 in response to enablement of a comparison enable signal COMP_EN.

An operation of the DCD circuit will be described with reference to FIGS. 1 and 2.

At a time point 211, the charge signal PREB may be enabled to a low level. At this time, the charger 113 may charge the first and second capacitors 111 and 112 with the supply voltage VDD in response to the low-enabled charge signal PREB.

At a time point 212, the enable signal DCD_EN may be enabled to a high level to turn on the enable unit 116. The enable unit 116 may control the first and second dischargers 114 and 115 to start a discharging operation. The first discharger 114 may discharge the first capacitor 111 while the clock CK is at the first level (for example, high level), and the second discharger 115 may discharge the second capacitor 112 while the clock CK is at the second level (for example, low level). Thus, when the high pulse width of the clock CK is wider than the low pulse width thereof, the first capacitor 111 may be discharged more than the second capacitor 112. When the low pulse width of the clock CK is wider than the high pulse width thereof, the second capacitor 112 may be discharged more than the first capacitor 111. The enable signal DCD_EN may stay enabled for the duty cycle detection operation during N cycles of the clock CK (i.e., N*tCK), where N is an integer equal to or more than 1.

At a time point 213 after the enable signal DCD_EN is disabled to a low level, the comparison enable signal COMP_EN may be enabled to a high level. In response to the comparison enable signal COMP_EN, the comparator 118 may be enabled to compare the voltage OUTB across the first capacitor 111 and the voltage OUT across the second capacitor 112, and generate the duty cycle detection result DCD_OUT as the comparison result. When the duty cycle detection result DCD_OUT is at a high level, it may indicate that the high pulse width of the clock CK is wider than the low pulse width thereof. When the duty cycle detection result DCD_OUT is at a low level, it may indicate that the low pulse width of the clock CK is wider than the high pulse width thereof.

In FIG. 2, the time points 211 to 213 may represent a one-cycle operation of the DCD circuit, and time points 221 to 223 may represent the next cycle operation of the DCD circuit.

Equation 1 below may represent the amount of discharge from each of the capacitors 111 and 112, under the supposition that the high pulse width and the low pulse width of the clock are equal to each other.

$$Δ Q = \frac{I \times N \times tCK}{2} = Δ V \times C \qquad [ Equation 1 ]$$

In Equation 1, denotation “I” represents the current amount of the current source 117, and “C” represents the capacity of the capacitor 111 or 112.

For the comparator 118 to operate at the optimal condition, an intermediate value between the voltage across the first capacitor 111 and the voltage across the second capacitor 112 needs to be set to one half of the supply voltage VDD (i.e., VDD/2). That is, the first and second capacitors 111 and 112 need to be discharged to the half of the supply voltage VDD from the supply voltage VDD corresponding to the state in which the first and second capacitors 111 and 112 are charged. When this condition is substituted for Equation 1, Equation 2 below may be acquired.

$$Δ V = \frac{V D D}{2} = \frac{I \times N \times tCK}{2 \times C} \qquad [ Equation 2 ]$$

When Equation 2 is arranged for the capacity “C” of the capacitor 111 or 112, Equation 3 below may be acquired.

$$C = N \times tCK \times \frac{1}{V D D} = N \times \frac{1}{f} \times \frac{I}{V D D} \qquad [ Equation 3 ]$$

In Equation 3, denotation “f” represents the frequency of the clock CK.

In Equation 3, the capacity “C” of the capacitor 111 or 112 represents the optimal capacity, at which the DCD circuit may be optimally operated. As known from Equation 3, the optimal capacities of the capacitors 111 and 112 may vary according to the frequency “f” of the clock CK.

That is, when the capacitors 111 and 112 have a fixed capacity, the DCD circuit may optimally operate only with a specific frequency corresponding to the fixed capacity. When the frequency of the clock CK is varied, the DCD circuit may not optimally operate.

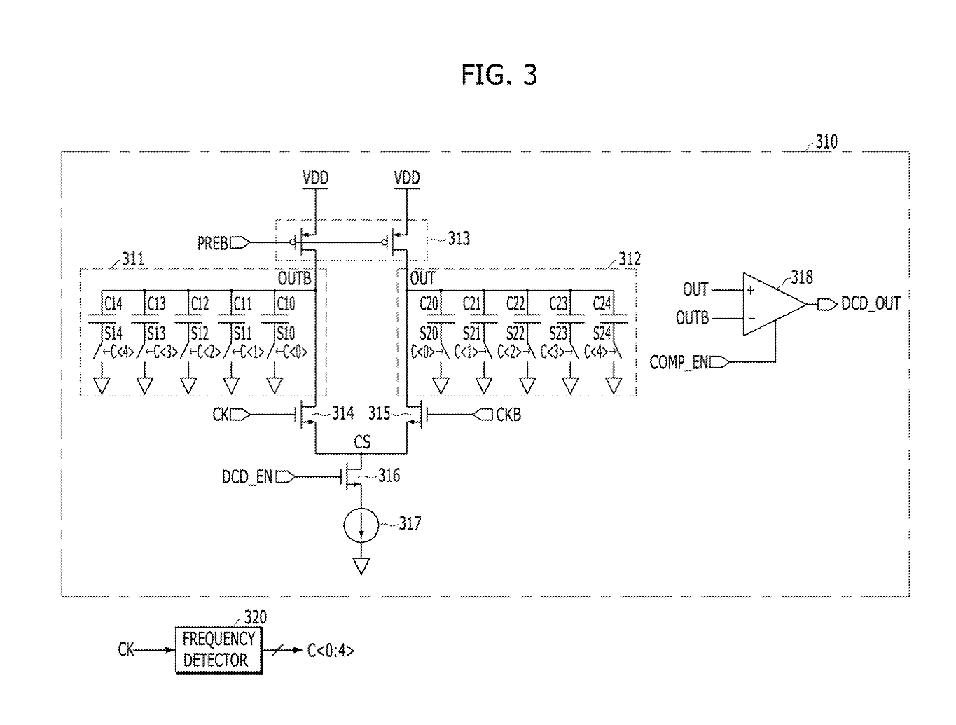

FIG. 3 is a configuration diagram of a DCD circuit according to another embodiment of the present invention.

Referring to FIG. 3, the DCD circuit may include a duty cycle detector 310 and a frequency detector 320. The duty cycle detector 310 may detect the duty cycle of a clock CK using first and second capacitor sets 311 and 312 which are discharged by the clock CK. The frequency detector 320 may detect the frequency of the clock CK. The capacities of the first and second capacitor sets 311 and 312 may be adjusted according to the frequency detection result C<0:4> of the frequency detector 320.

The duty cycle detector 310 may include the first capacitor set 311, the second capacitor set 312, a charger 313, a first discharger 314, a second discharger 315, an enable unit 316, a current source 317, and a comparator 318.

The first capacitor set 311 may include a plurality of capacitors C10 to C14 coupled in parallel to one another and a plurality of switches S10 to S14 for turning on/off the respective capacitors C10 to C14. The switches S10 to S14 may be turned on/off in response to the frequency detection result C<0:4>, respectively. The frequency detection result C<0:4> may include a binary code and the capacities of the capacitors C10 to C14 may have a binary weight. That is, the capacity of the capacitors C10 to C14 may be doubled at each stage from the capacitor C10 to the capacitor C14. The capacity of the first capacitor set 311 may become smaller as the frequency of the clock CK increases. Since the frequency detection result C<0:4> has a larger value as the frequency of the clock CK is high, the first capacitor set 311 may have a small capacity as the code value of the frequency detection result C<0:4> increases. That is, each of the switches S10 to S14 may be turned on when a code of the frequency detection result C<0:4> corresponding to the switch has a value of 0, and turned off when the code corresponding to the switch has a value of 1. For example, the switch S11 may be turned on when the code C<1> is “0” and turned off when the code C<1> is “1”, and the switch S13 may be turned on when the code C<3> is “0” and turned off when the code C<3> is “1”.

The second capacitor set 312 may have similar structure as the first capacitor set 311. The second capacitor set 312 may include a plurality of capacitors C20 to C24 coupled in parallel to one another and a plurality of switches S20 to S24 for turning on/off the respective capacitors C20 to C24. The switches S20 to S24 may be turned on/off in response to the frequency detection result C<0:4>, respectively. The capacities of the capacitors C20 to C24 may have a binary weight. The capacity of the second capacitor set 312 may become smaller as the frequency of the clock CK increases. Each of the switches S20 to S24 may be turned on when a code of the frequency detection result C<0:4> corresponding to the switch has a value of 0, and turned off when the code corresponding to the switch has a value of 1.

The charger 313, the first discharger 314, the second discharger 315, the enable unit 316, the current source 317, and the comparator 318 may be the same as the charger 113, the first discharger 114, the second discharger 115, the enable unit 116, the current source 117, and the comparator 118 of FIG. 1.

FIG. 3 illustrates as an example that the duty cycle detector 310 detects the duty cycle of the clock CK by discharging the first and second capacitor sets 311 and 312 in response to the clock CK. However, the invention is not limited in this way. For example, the duty cycle detector 310 may detect the duty cycle of the clock CK by charging the first and second capacitor sets 311 and 312 in response to the clock CK. For example, in a state where the first and second capacitor sets 311 and 312 are discharged, the duty cycle detector 310 may charge the first capacitor set 311 when the clock CK is at a first level while the duty cycle detector 310 may charge the second capacitor set 312 when the clock CK is at a second level. Then, the duty cycle detector 410 may compare the voltage across the first capacitor set 311 and the voltage across the second capacitor set 312 for detecting the duty cycle of the clock CK.

Alternatively, the duty cycle detector 310 may detect the duty cycle of the clock CK by charging and discharging the first and second capacitor sets 311 and 312 in response to the clock CK. For example, when the clock CK is at the first level, the duty cycle detector 310 may charge the first capacitor set 311 and discharge the second capacitor set 312. When the clock CK is at the second level, the duty cycle detector 310 may discharge the first capacitor set 311 and charge the second capacitor set 312. Then, the duty cycle detector 310 may compare the voltage across the first capacitor set 311 and the voltage across the second capacitor set 312 for detecting the duty cycle of the clock CK.

Furthermore, FIG. 3 illustrates as an example that the duty cycle detector 310 uses two capacitor sets 311 and 312 for detecting the duty cycle of the clock CK. However, the number of capacitor sets which the duty cycle detector 310 uses to detect the duty cycle of the clock CK may be changed.

The frequency detector 320 may detect the frequency of the clock CK and generate the frequency detection result C<0:4>. The frequency detection result C<0:4> may include a binary code, and have a larger value as the frequency of the clock CK becomes higher.

In the embodiment of FIG. 3, the capacities of the capacitor sets 311 and 312 which the duty cycle detector 310 uses to detect the duty cycle of the clock CK may be adjusted according to the frequency of the clock CK detected by the frequency detector 320. Thus, although the frequency of the clock CK may be changed, the capacitor sets 311 and 312 may always have the optimal capacity required for the duty cycle detection. That is, although the frequency of the clock CK may vary, the DCD circuit may always operate with high precision.

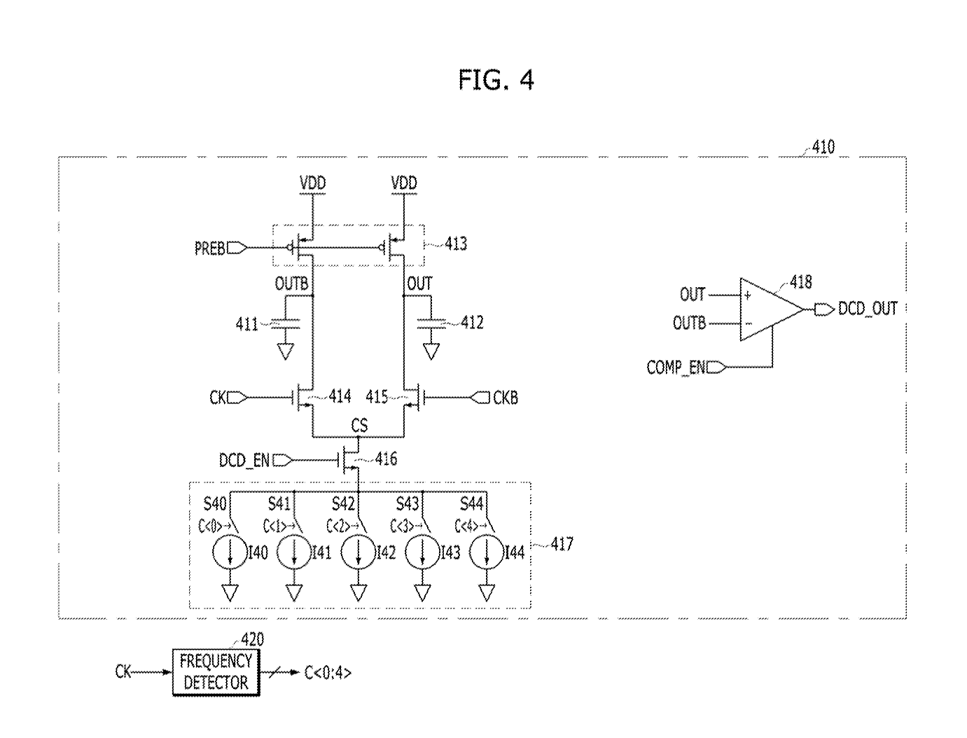

FIG. 4 is a configuration diagram of a DCD circuit according to another embodiment of the present invention.

Referring to FIG. 4, the DCD circuit may include a duty cycle detector 410 and a frequency detector 420. The duty cycle detector 410 may detect the duty cycle of a clock CK using first and second capacitors 411 and 412 which are discharged by the clock CK. The frequency detector 420 may detect the frequency of the clock CK. Furthermore, the amount of discharge current for discharging the first and second capacitors 411 and 412 may be adjusted according to a frequency detection result C<0:4> of the frequency detector 420.

The duty cycle detector 410 may include the first capacitor 411, the second capacitor 412, a charger 413, a first discharger 414, a second discharger 415, an enable unit 416, a current source set 417, and a comparator 418. The first capacitor 411, the second capacitor 412, the charger 413, the first discharger 414, the second discharger 415, the enable unit 416, and the comparator 418 may be the same as the first capacitor 111, the second capacitor 112, the charger 113, the first discharger 114, the second discharger 115, the enable unit 116, and the comparator 118 of FIG. 1, respectively.

The current source set 417 may include a plurality of current sources I40 to I44 coupled in parallel to one another and a plurality of switches S40 to S44 for turning on/off the respective current sources I40 to I44. The switches S40 to S44 may be turned on/off in response to the frequency detection result C<0:4>, respectively. The frequency detection result C<0:4> may include a binary code and the current amounts of the current sources I40 to I44 may have a binary weight. For example, the current amount of the current sources I40 to I44 may be doubled at each stage from the current source I40 to the current source I44. The current amount of the current source set 417 may increase as the frequency of the clock CK increases. Since the frequency detection result C<0:4> has a large value as the frequency of the clock CK is high, the current source set 417 may have a large current amount as the code value of the frequency detection result C<0:4> increases. That is, each of the switches S40 to S44 may be turned on when the code of the frequency detection result C<0:4> corresponding to the switch has a value of 1, and turned off when the code corresponding to the switch has a value of 0. For example, the switch S41 may be turned on when the code C<1> is “1” and turned off when the code C<1> is “0”, and the switch S43 may be turned on when the code C<3> is “1” and turned off when the code C<3> is “0”.

FIG. 4 illustrates as an example that the duty cycle detector 410 detects the duty cycle of the clock CK by discharging the first and second capacitors 411 and 412 in response to the clock CK. However, the duty cycle detector 410 may detect the duty cycle of the clock CK by charging the first and second capacitors 411 and 412 in response to the clock CK. For example, in a state where the first and second capacitors 411 and 412 are discharged, the duty cycle detector 410 may charge the first capacitor 411 when the clock CK is at a first level while the duty cycle detector 410 may charge the second capacitor 412 when the clock CK is at a second level. Then, the duty cycle detector 410 may compare the voltages across the first and second capacitors 411 and 412 for detecting the duty cycle of the clock CK.

Alternatively, the duty cycle detector 410 may detect the duty cycle of the clock CK by charging and discharging the first and second capacitors 411 and 412 in response to the clock CK. For example, when the clock CK is at the first level, the duty cycle detector 410 may charge the first capacitor 411 and discharge the second capacitor 412. When the clock CK is at the second level, the duty cycle detector 410 may discharge the first capacitor 411 and charge the second capacitor 412. Then, the duty cycle detector 410 may compare the voltages across the first and second capacitors 411 and 412 for detecting the duty cycle of the clock CK.

Furthermore, it is noted that although FIG. 4 illustrates, as an example, that the duty cycle detector 410 may use two capacitors 411 and 412 for detecting the duty cycle of the clock CK, the number of capacitors which the duty cycle detector 410 uses for detecting the duty cycle of the clock CK may be changed.

Furthermore, FIG. 4 illustrates as an example that the current source set 417 may be used to adjust the amount of discharge current for discharging the first and second capacitors 411 and 412. However, it is noted, that the current source set 417 may be used to adjust the amount of charge current for charging the first and second capacitors 411 and 412, or may be used to adjust the charge and discharge current amounts for charging and discharging the first and second capacitors 411 and 412.

The frequency detector 420 may detect the frequency of the clock CK and generate the frequency detection result C<0:4>. The frequency detection result C<0:4> may include a binary code, and have a larger value as the frequency of the clock CK becomes higher.

In the embodiment of FIG. 4, the discharge current amounts of the capacitors 411 and 412 which the duty cycle detector 410 uses to detect the duty cycle of the clock CK may be adjusted to increase as the frequency of the clock CK detected by the frequency detector 420 increases. This operation may have the same effect as the capacities of the capacitor sets 311 and 312 of FIG. 3 are adjusted to decrease as the detected frequency of the clock CK becomes higher. That is, although the frequency of the clock CK may vary, the DCD circuit may always operate with high precision.

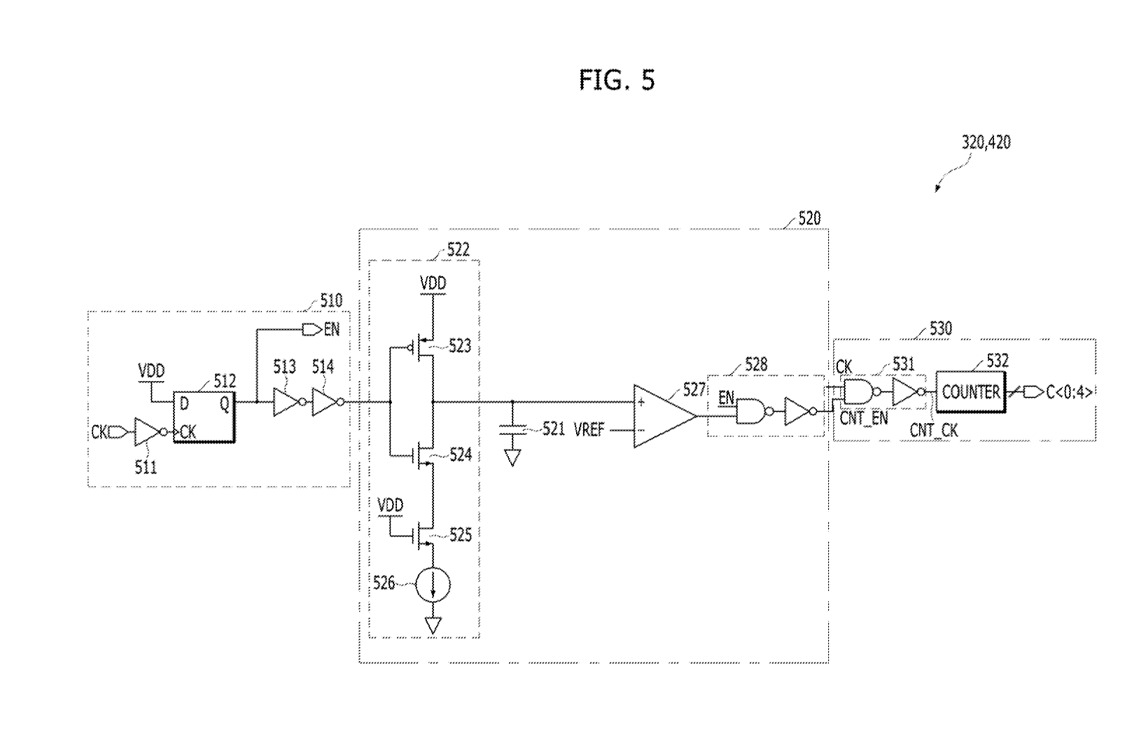

FIG. 5 is a configuration diagram illustrating a first embodiment of the frequency detector 320 or 420 of FIG. 3 or 4.

Referring to FIG. 5, the frequency detector 320 or 420 may include a discharger enable signal generation unit 510, a period setting unit 520, and a counter unit 530.

The discharger enable signal generation unit 510 may generate a discharger enable signal EN. The discharger enable signal generation unit 510 may include a D flip-flop 512 and inverters 511, 513, and 514. The discharger enable signal EN may stay disabled to a low level. Then, when the clock CK transmits from a high level to a low level, the discharger enable signal EN may be enabled to a high level.

The period setting unit 520 may generate a counting period signal CNT_EN which is enabled for a predetermined time. The period setting unit 520 may include a reference capacitor 521, a discharger 522, a comparator 527, and a period signal generator 528.

The discharger 522 may charge the reference capacitor 521 when the discharger enable signal EN is disabled, and discharge the reference capacitor 521 when the discharger enable signal EN is enabled. The discharger 522 may include a PMOS transistor 523, NMOS transistors 524 and 525, and a current source 526. The PMOS transistor 523, the NMOS transistors 524 and 525, and the current source 526 of the discharger 522 may be preferably configured in a similar manner respectively to the charger 313, the first discharger 314, the enable unit 316, and the current source 317 of the duty cycle detector 310. The capacity of the reference capacitor 521 may be preferably similar to the maximum capacity of the first capacitor set 311.

The comparator 527 may compare the voltage across the reference capacitor 521 with the reference voltage VREF. The reference voltage VREF may be one half of the supply voltage VDD. The period signal generator 528 may generate the counting period signal CNT_EN in response to the discharger enable signal EN and an output signal of the comparator 527. For example, the period signal generator 528 may enable the counting period signal CNT_EN to a high level while the output signal of the comparator 527 is high and the discharger enable signal EN is enabled to a high level. Otherwise, the period signal generator 528 may deactivate the counting period signal CNT_EN. The period signal generator 528 may include a NAND gate and an inverter as illustrated in FIG. 5.

The counter unit 530 may generate the frequency detection result C<0:N> by counting a number of enablement times of the clock CK during enablement of the counting period signal CNT_EN. The counter unit 530 may include a counting clock generator 531 and a counter 532.

The counting clock generator 531 may output the clock CK as a counting clock CNT_CK during enablement of the counting period signal CNT_EN, and deactivate the counting clock CNT_CK during disablement of the counting period signal CNT_EN. The disabled counting clock CNT_CK may not toggle and stay at a low level. The counting clock generator 531 may include a NAND gate and an inverter as illustrated in FIG. 5.

The counter 532 may generate the frequency detection result C<0:4> as a binary code by counting the number of enablement times of the counting clock CNT_CK. As the frequency of the clock CK becomes higher, the frequency detection result C<0:4> may have a larger value.

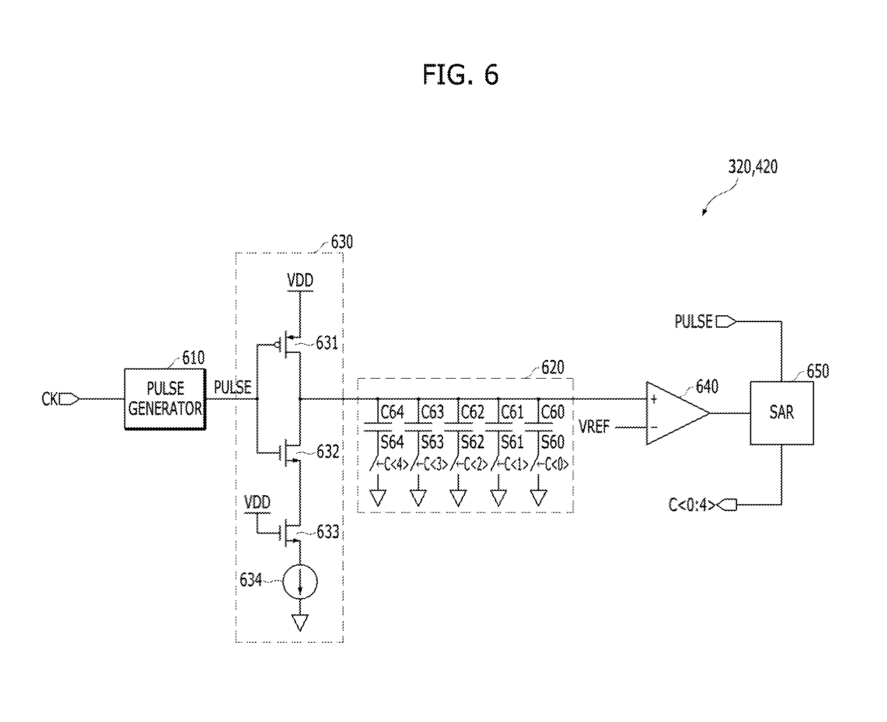

FIG. 6 is a configuration diagram illustrating a second embodiment of the frequency detector 320 or 420 of FIG. 3 or 4.

Referring to FIG. 6, the frequency detector 320 or 420 may include a pulse generator 610, a replica capacitor set 620, a discharger 630, a comparator 640, a successive approximation register (SAR) 650.

The pulse generator 610 may receive the clock CK, and generate a pulse signal PULSE having a pulse width corresponding to the N cycles of the clock CK (N*tCK), which is the same as the enable signal DCD_EN. The pulse signal PULSE may be periodically enabled.

The replica capacitor set 620 may have a capacity adjustable in response to a frequency detection result C<0:4>. The replica capacitor set 620 may include a plurality of capacitors C60 to C64 coupled in parallel and a plurality of switches S60 to S64 for turning on/off the respective capacitors C60 to C64, respectively. The replica capacitor set 620 may be configured in the same manner as the first and second capacitor sets 311 and 312 of FIG. 3.

The discharger 630 may charge the replica capacitor set 620 during disablement of the pulse signal PULSE. The discharger 630 may discharge the replica capacitor set 620 during enablement of the pulse signal PULSE. The discharger 630 may be configured in the same manner as the discharger 522 of FIG. 5.

The comparator 640 may compare the voltage across the replica capacitor set 620 with the reference voltage VREF.

The SAR 650 may generate the frequency detection result C<0:4> in response to an output signal of the comparator 640. For example, the SAR 650 may generate the frequency detection result C<0:4> through a successive approximation in response to the output signal of the comparator 640 when the pulse signal PULSE transitions from a high level to a low level. For example, assuming that the frequency detection result C<0:4> has the initial value of (0, 1, 1, 1, 1), the SAR 650 may determine the value of the highest position C<4> of the frequency detection result C<0:4> in response to the output signal of the comparator 640 when the pulse signal PULSE is firstly disabled, and determine the value of the second highest position C<3> of the frequency detection result C<0:4> in response to the output signal of the comparator 640 when the pulse signal PULSE is secondly disabled. As a result, the frequency detection result C<0:4> may be generated for determining the capacity of the replica capacitor set 620 so that the replica capacitor set 620 is discharged to the reference voltage VREF by the discharger 630 during enablement of the pulse signal PULSE. Since enablement duration of the pulse signal PULSE depends on the frequency of the clock CK, the frequency detection result C<0:4> may indicate the frequency of the clock CK.

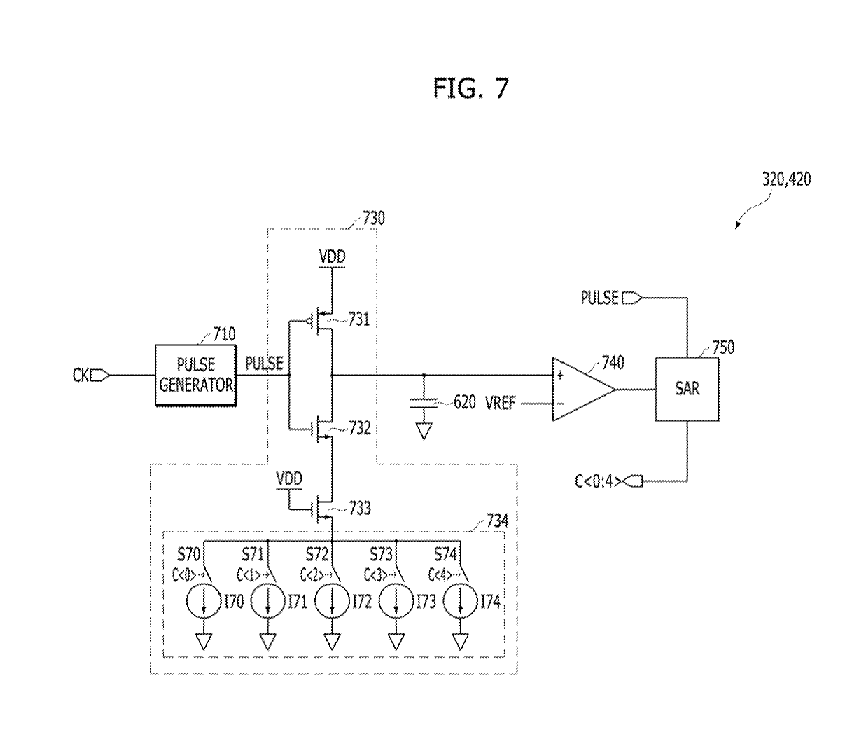

FIG. 7 is a configuration diagram illustrating a third embodiment of the frequency detector 320 or 420 of FIG. 3 or 4.

Referring to FIG. 7, the frequency detector 320 or 420 may include a pulse generator 710, a reference capacitor 720, a discharger 730, a comparator 740, and a SAR 750.

The pulse generator 710 may receive the clock CK, and generate a pulse signal PULSE having a pulse width corresponding to the N cycles of the clock CK (N*tCK), which is the same as the enable signal DCD_EN. The pulse signal PULSE may be periodically enabled.

The discharger 730 may charge the reference capacitor 720 during disablement of the pulse signal PULSE, and discharge the reference capacitor 720 during enablement of the pulse signal PULSE. The discharger 730 may have a configuration in which the current source 634 of the discharger 630 of FIG. 6 is replaced with a replica current source set 734. The replica current source set 734 may have the same configuration as the current source set 417, and the current amount of the replica current source set 734 may be adjusted according to the frequency detection result C<0:4>. That is, the discharge current amount of the discharger 730 may be adjusted according to the frequency detection result C<0:4>.

The comparator 740 may compare the voltage across the reference capacitor 720 with the reference voltage VREF.

The SAR 750 may generate the frequency detection result C<0:4> in response to an output signal of the comparator 740. For example, the SAR 750 may generate the frequency detection result C<0:4> through a successive approximation in response to the output signal of the comparator 740 when the pulse signal PULSE transitions from a high level to a low level. For example, assuming that the frequency detection result C<0:4> has the initial value of (0, 1, 1, 1, 1), the SAR 750 may determine the value of the highest position C<4> of the frequency detection result C<0:4> in response to the output signal of the comparator 740 when the pulse signal PULSE is firstly disabled, and determine the value of the second highest position C<3> of the frequency detection result C<0:4> in response to the output signal of the comparator 740 when the pulse signal PULSE is secondly disabled. As a result, the frequency detection result C<0:4> may be generated to determine the current amount of the replica current source set 734 of the discharger 730 so that the reference capacitor 720 is discharged to the reference voltage VREF by the discharger 730 during enablement of the pulse signal PULSE. Since enablement duration of the pulse signal PULSE depends on the frequency of the clock CK, the frequency detection result C<0:4> may indicate the frequency of the clock CK.

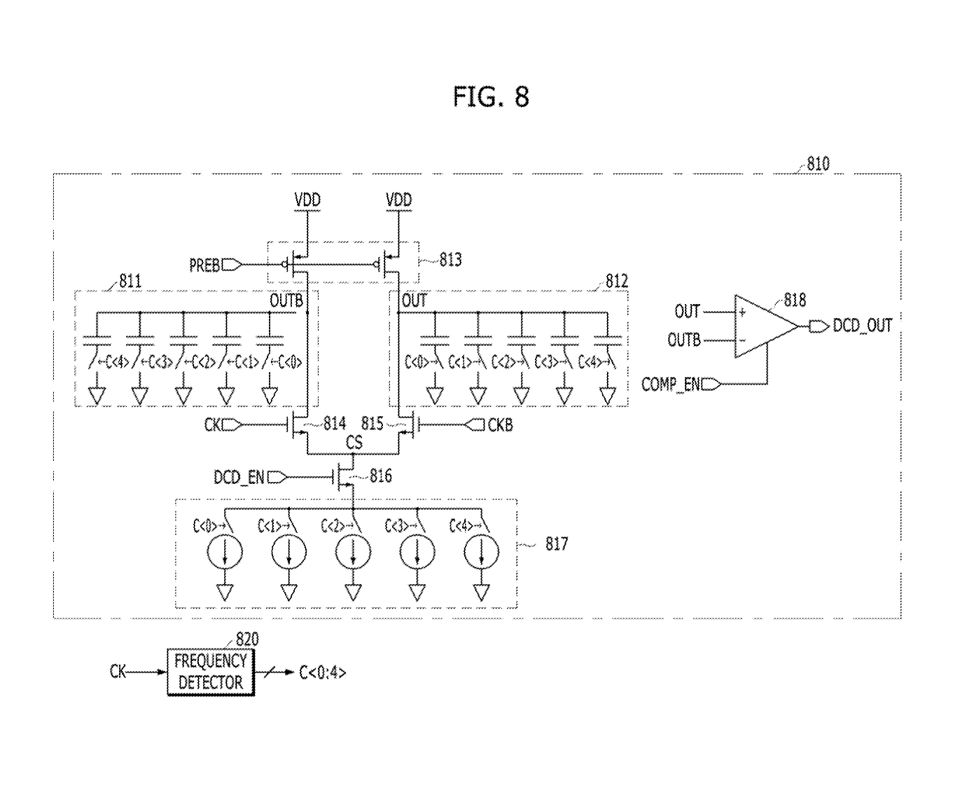

FIG. 8 is a configuration diagram of a DCD circuit according to another embodiment of the present invention.

Referring to FIG. 8, the DCD circuit may include a duty cycle detector 810 and a frequency detector 820. The duty cycle detector 810 may detect the duty cycle of a clock CK using first and second capacitor sets 811 and 812 which are discharged by the clock CK. The frequency detector 820 may detect the frequency of the clock CK. The capacities of the first and second capacitor sets 811 and 812 may be adjusted according to the frequency detection result C<0:4> of the frequency detector 820, and the amount of discharge current for discharging the first and second capacitor sets 811 and 812 may be adjusted according to the frequency detection result C<0:4>.

The capacities of the first and second capacitor sets 811 and 812 may be adjusted according to the frequency detection result C<0:4>, in a similar manner to the first and second capacitor sets 311 and 312 described with reference to FIG. 3. Further, the current source set 817 may adjust the amount of discharge current for discharging the first and second capacitor sets 811 and 812 according to the frequency detection result C<0:4>, in a similar manner to the current source set 417 described with reference to FIG. 4. The other elements of the DCD circuit of FIG. 8 may be the same as the corresponding ones described with reference to FIGS. 3 to 7.

According to various embodiments of the present invention, a DCD circuit having improved precision is provided. In particular, although the frequency of a clock may vary, the DCD circuit may be always operated with high precision.

Although various embodiments have been described for illustrative purposes, it will be apparent to those skilled in the art that various changes and modifications may be made without departing from the spirit and/or scope of the invention as defined in the following claims.

What is claimed is:

1. A duty cycle detector (DCD) circuit comprising:
a duty cycle detector suitable for detecting a duty of a clock, the duty cycle detector including one or more capacitor sets which are charged, discharged or charged and discharged by the clock; and
a frequency detector suitable for detecting a frequency of the clock,
wherein each of the one or more capacitor sets has an adjustable capacity according to the frequency detection result of the frequency detector.

2. The DCD circuit of claim 1, wherein the capacity of each of the one or more capacitor sets decreases as the frequency of the clock becomes higher, and increases as the frequency of the clock becomes lower.

3. The DCD circuit of claim 1, wherein each of the one or more capacitor sets comprises:
a plurality of capacitors coupled in parallel to one another; and
a plurality of switches suitable for turning on/off the capacitors, respectively, according to the frequency detection result.

4. The DCD circuit of claim 1, wherein the frequency detector comprises:
a period setting unit suitable for enabling a counting period signal for a predetermined time; and
a counter unit suitable for generating the frequency detection result by counting a number of enablement times of the clock during enablement of the counting period signal.

5. The DCD circuit of claim 4, wherein the period setting unit comprises:
a reference capacitor;
a discharger suitable for charging the reference capacitor during disablement of a discharger enable signal, and discharging the reference capacitor during enablement of the discharger enable signal;
a comparator suitable for comparing the voltage across the reference capacitor with the level of a reference voltage; and
a period signal generator suitable for generating the counting period signal in response to the discharger enable signal and an output signal of the comparator.

6. The DCD circuit of claim 4, wherein the counter unit comprises:
a counting clock generator suitable for outputting the clock as a counting clock during enablement of the counting period signal, and deactivating the counting clock during disablement of the counting period signal; and
a counter suitable for generating the frequency detection result by counting the number of enablement times of the counting clock.

7. The DCD circuit of claim 1, wherein the frequency detector comprises:
a pulse generator suitable for generating a pulse signal having a pulse width corresponding to N cycles of the clock, where N is an integer equal to or more than 1;
a replica capacitor set as a replica of one of the capacitor sets;
a discharger suitable for charging the replica capacitor set during disablement of the pulse signal, and discharging the replica capacitor set during enablement of the pulse signal;
a comparator suitable for comparing the voltage across the replica capacitor set with the level of a reference voltage; and
a successive approximation register (SAR) suitable for generating the frequency detection result in response to an output signal of the comparator.

8. The DCD circuit of claim 1, wherein the frequency detector comprises:
a pulse generator suitable for generating a pulse signal having a pulse width corresponding to N cycles of the clock, where N is an integer equal to or more than 1;
a reference capacitor;
a discharger suitable for charging the reference capacitor during disablement of the pulse signal, and discharging the reference capacitor during enablement of the pulse signal, wherein the discharger adjusts amount of discharge current according to the frequency detection result;
a comparator suitable for comparing the voltage across the reference capacitor with the level of a reference voltage; and
a SAR suitable for generating the frequency detection result in response to an output signal of the comparator.

9. The DCD circuit of claim 1,
wherein the one or more capacitor sets comprise first and second capacitor sets, and
wherein the duty cycle detector discharges the first capacitor set when the clock is at a first level, discharges the second capacitor set when the clock is at a second level, and generate the duty cycle detection result by comparing the discharge amounts of the first and second capacitor sets.

10. The DCD circuit of claim 9, wherein the duty cycle detector further comprises:
a charger suitable for charging the first and second capacitor sets in response to a charge signal;
a first discharger suitable for discharging the first capacitor set when the clock is at the first level;
a second discharger suitable for discharging the second capacitor set when the clock is at the second level; and
a comparator suitable for generating the duty cycle detection result by comparing the voltage across the first capacitor set to the voltage across the second capacitor set.

11. A DCD circuit comprising:
a duty cycle detector including one or more capacitors which are charged, discharged or charged and discharged by a clock, and suitable for detecting a duty of the clock; and
a frequency detector suitable for detecting a frequency of the clock,
wherein the duty cycle detector adjusts a charge current amount, a discharge current amount, or a charge and discharge current amount of the one or more capacitors according to the frequency detection result of the frequency detector.

12. The DCD circuit of claim 11, wherein the charge current amount, the discharge current amount, or the charge and discharge current amount increases as the frequency of the clock is high, and decreases as the frequency of the clock is low.

13. The DCD circuit of claim 11,
wherein the duty cycle detector comprises a current source set suitable for adjusting the charge current amount, the discharge current amount, or the charge and discharge current amount, and
the current source set comprises:
a plurality of current sources coupled in parallel to one another; and
a plurality of switches suitable for turning on/off the current sources, respectively, according to the frequency detection result.

14. The DCD circuit of claim 11, wherein the frequency detector comprises:
a period setting unit suitable for enabling a counting period signal for a predetermined time; and
a counter unit suitable for generating the frequency detection result by counting a number of enablement times of the clock during enablement of the counting period signal.

15. The DCD circuit of claim 14, wherein the period setting unit comprises:
a reference capacitor;
a discharger suitable for charging the reference capacitor during disablement of a discharger enable signal, and discharging the reference capacitor during enablement of the discharger enable signal;
a comparator suitable for comparing the voltage across the reference capacitor with the level of a reference voltage; and
a period signal generator suitable for generating the counting period signal in response to the discharger enable signal and an output signal of the comparator.

16. The DCD circuit of claim 14, wherein the counter unit comprises:
a counting clock generator suitable for outputting the received clock as a counting clock during enablement of the counting period signal, and deactivating the counting clock during disablement of the counting period signal; and
a counter suitable for generating the frequency detection result by counting the number of enablement times of the counting clock.

17. The DCD circuit of claim 11, wherein the frequency detector comprises:
a pulse generator suitable for generating a pulse signal having a pulse width corresponding to N cycles of the clock, where N is an integer equal to or more than 1;
a replica capacitor set having an adjustable capacity according to the frequency detection result;
a discharger suitable for charging the replica capacitor set during disablement of the pulse signal, and discharging the replica capacitor set during enablement of the pulse signal;
a comparator suitable for comparing the voltage across the replica capacitor set with the level of a reference voltage; and
a successive approximation register (SAR) suitable for generating the frequency detection result in response to an output signal of the comparator.

18. The DCD circuit of claim 11, wherein the frequency detector comprises:
a pulse generator suitable for generating a pulse signal having a pulse width corresponding to N cycles of the clock, where N is an integer equal to or more than 1;
a reference capacitor;
a discharger suitable for charging the reference capacitor during disablement of the pulse signal, and discharging the reference capacitor set during enablement of the pulse signal, wherein the discharger adjusts amount of discharge current according to the frequency detection result;
a comparator suitable for comparing the voltage across the reference capacitor with the level of a reference voltage; and
a SAR suitable for generating the frequency detection result in response to an output signal of the comparator.

19. The DCD circuit of claim 11,
wherein the one or more capacitor sets comprise first and second capacitor sets, and
wherein the duty cycle detector discharges the first capacitor set when the clock is at a first level, discharges the second capacitor set when the clock is at a second level, and generate the duty cycle detection result by comparing the discharge amounts of the first and second capacitors.

20. The DCD circuit of claim 19, wherein the duty cycle detector further comprises:
a charger suitable for charging the first and second capacitor sets in response to a charge signal;
a first discharger suitable for discharging the first capacitor set when the clock is at the first level;
a second discharger suitable for discharging the second capacitor set when the clock is at the second level;
a current source set suitable for adjusting discharge current amounts of the first and second dischargers according to the frequency detection result; and
a comparator suitable for generating the duty cycle detection result by comparing the voltage across the first capacitor set to the voltage across the second capacitor set.

21. A DCD circuit comprising:
a duty cycle detector including one or more capacitor sets which are charged, discharged, or charged and discharged by a clock, and suitable for detecting a duty of the clock; and
a frequency detector suitable for detecting a frequency of the clock,
wherein each of the one or more capacitor sets has an adjustable capacity according to the frequency detection result of the frequency detector, and
the duty cycle detector adjusts a charge current amount, a discharge current amount, or a charge and discharge current amount of each of the capacitor sets according to the frequency detection result of the frequency detector.
